(19) United States
(12) Patent Application Publication
(10) Pub. No.: US 2025/0233517 A1
(43) Pub. Date: Jul. 17, 2025

(54) CHARGE PUMP NOISE CANCELLING TECHNIQUE WITH TAIL CURRENT SOURCE CHOPPING

(71) Applicant: Infinera Corp., San Jose, CA (US)

(72) Inventors: Fu-Tai An, San Jose, CA (US); Ali Kiaei, San Jose, CA (US)

(21) Appl. No.: 19/022,725

(22) Filed: Jan. 15, 2025

Related U.S. Application Data
(60) Provisional application No. 63/621,071, filed on Jan. 15, 2024.

(51) Int. Cl. H02M 3/07; H03L 7/089

(52) U.S. Cl. CPC H02M 3/07; H03L 7/0895

(57) ABSTRACT

A charge pump includes an output node having a control current signal and a reference current input. The charge pump comprises a tail transistor configured to output a tail current and a DN transistor, coupled to the output node and the tail transistor responsive to a DN signal from a PFD. A voltage buffer receives the control current signal from the output node. A discharge transistor, controlled by a discharge signal, couples the sampling capacitor's bottom plate and a third switch with the tail transistor. During a first period, the sampling capacitor's top plate is connected to the buffer output through the first switch while the bottom plate supplies a discharge current to the DN transistor. During a second period, an offset current is provided to the output node and a down current is provided to the tail transistor from the top plate through a second switch and third switch.

### CROSS-REFERENCE TO RELATED APPLICATIONS

The present application claims priority to Provisional Patent Application U.S. Ser. No. 63/621,071 titled “Charge pump noise cancelling technique with tail current source chopping” filed on Jan. 15, 2024, the entire content of which is hereby expressly incorporated herein by reference in its entirety.

### BACKGROUND

Traditional phase-locked loops (PLLs) are widely used in various electronic systems for frequency synthesis and clock generation. In traditional PLL implementations, analog charge-pump based topologies remain prevalent due to their proven reliability and ability to achieve high performance at elevated output frequencies. These traditional designs, however, face significant challenges related to phase noise, particularly within the loop bandwidth where charge pump noise becomes a dominant factor affecting overall PLL performance.

Traditional approaches to mitigating charge pump noise have focused on increasing the size of tail current source transistors. While this technique can reduce noise contributions from individual transistors, it introduces substantial area overhead on the integrated circuit. Moreover, the effectiveness of this traditional approach diminishes beyond certain transistor sizes, as the increased parasitic capacitance begins to adversely affect PLL performance. This limitation creates a practical ceiling for phase noise reduction using conventional sizing techniques.

Additionally, traditional PLL architectures typically generate signal current and offset current from separate circuit branches, resulting in four primary noise-contributing transistors. This conventional approach necessitates significant upsizing of all four transistors to achieve acceptable noise performance, leading to excessive area consumption and increased parasitic effects. The presence of multiple independent noise sources in these traditional designs fundamentally limits the achievable phase noise performance while maintaining reasonable area constraints.

Alternative traditional implementations have attempted to address these limitations by generating both signal and offset currents from a single circuit branch. While this approach reduces the number of noise-contributing transistors from four to two, it maintains separate, uncorrelated noise sources that still require substantial transistor sizing. Furthermore, these traditional single-branch implementations often require routing significant portions of the current sources to ground, resulting in unnecessary power consumption without corresponding performance benefits.

Traditional solutions have reached practical limits in terms of balancing these competing requirements, particularly as modern applications demand increasingly stringent performance specifications.

Thus, a need exists for improvements resulting in more efficient PLL architectures that can achieve superior phase noise performance while minimizing both area and power consumption. It is to such improvements the present disclosure is directed.

### SUMMARY

The problem of charge pump noise in PLL designs while maintaining reasonable area consumption and power efficiency is solved by the methods and systems described herein. Such systems and methods include: a charge pump circuit comprising an output node, a reference current input, a tail transistor, a DN transistor, a sampling capacitor, a voltage buffer, a plurality of switches, and a discharge transistor. The output node has a control current signal. The reference current input is configured to receive a reference current. The tail transistor has a first source, a first drain, and a first gate. The first gate is configured to receive the reference current. The first source is configured to receive a down current. The first drain is configured to output an N-side tail current. The DN transistor has a DN source coupled to the output node and is operable to receive the down current, a DN drain coupled to the first source of the tail transistor, and a DN gate operable to receive a DN signal from a phase-frequency detector. The DN gate is operable to connect the DN source to the DN drain in response to the DN signal from the phase-frequency detector being high. The sampling capacitor has a top plate and a bottom plate. The voltage buffer has a first buffer input, a second buffer input, and a buffer output. The first buffer input is coupled to the output node to receive the control current signal. The second buffer input is coupled to the buffer output. The plurality of switches comprises a first switch, a second switch and a third switch. The first switch is coupled between the top plate of the sampling capacitor and the buffer output. The first switch has a first switch state being one of: closed and opened. The second switch is coupled between the output node and the top plate of the sampling capacitor. The second switch has a second switch state being one of: closed and opened. The third switch is coupled between the bottom plate of the sampling capacitor and the buffer output. The third switch has the second switch state. The discharge transistor has a discharge source disposed between the third switch and the bottom plate of the sampling capacitor, a discharge drain coupled to the first source of the tail transistor, and a discharge gate operable to receive a discharge signal. In a first configuration, the first switch state is closed to electrically couple the top plate of the sampling capacitor to the buffer output and the second switch state is opened to electrically couple the bottom plate of the sampling capacitor to the discharge source of the discharge transistor to supply a discharge current to the discharge source. In a second configuration, the first switch state is opened and the second switch state is closed to electrically couple the bottom plate of the sampling capacitor to the buffer output and to electrically couple the top plate of the sampling capacitor to the output node to provide both an offset current to the output node and the down current to the tail transistor.

The problem of charge pump noise in PLL designs while maintaining reasonable area consumption and power efficiency is further solved by a phase-locked loop system comprising a phase-frequency detector, a charge pump, a loop filter, a voltage-controlled oscillator, and a frequency divider. The phase-frequency detector is operable to receive a reference clock signal and a feedback clock signal and to transmit a DN signal and a UP signal. The charge pump comprises a PMOS-side circuitry, an output node, a reference current input, a tail transistor, a DN transistor, a sampling capacitor, a voltage buffer, a plurality of switches, and a discharge transistor. The PMOS-side circuitry is operable to receive the UP signal from the phase-frequency detector. The output node has a control current signal. The reference current input is configured to receive a reference current. The tail transistor has a first source, a first drain, and a first gate. The first gate is configured to receive the reference current. The first source is configured to receive a down current. The first drain is configured to output an N-side tail current. The DN transistor has a DN source coupled to the output node and is operable to receive the down current, a DN drain coupled to the first source of the tail transistor, and a DN gate operable to receive a DN signal from a phase-frequency detector. The DN gate is operable to connect the DN source to the DN drain in response to the DN signal from the phase-frequency detector being high. The sampling capacitor has a top plate and a bottom plate. The voltage buffer has a first buffer input, a second buffer input, and a buffer output. The first buffer input is coupled to the output node to receive the control current signal. The second buffer input is coupled to the buffer output. The plurality of switches comprises a first switch, a second switch and a third switch. The first switch is coupled between the top plate of the sampling capacitor and the buffer output. The first switch has a first switch state being one of: closed and opened. The second switch is coupled between the output node and the top plate of the sampling capacitor. The second switch has a second switch state being one of: closed and opened. The third switch is coupled between the bottom plate of the sampling capacitor and the buffer output. The third switch has the second switch state. The discharge transistor has a discharge source disposed between the third switch and the bottom plate of the sampling capacitor, a discharge drain coupled to the first source of the tail transistor, and a discharge gate operable to receive a discharge signal. In a first configuration, the first switch state is closed to electrically couple the top plate of the sampling capacitor to the buffer output and the second switch state is opened to electrically couple the bottom plate of the sampling capacitor to the discharge source of the discharge transistor to supply a discharge current to the discharge source. In a second configuration, the first switch state is opened and the second switch state is closed to electrically couple the bottom plate of the sampling capacitor to the buffer output and to electrically couple the top plate of the sampling capacitor to the output node to provide both an offset current to the output node and the down current to the tail transistor. The loop filter is in communication with the output node and operable to receive the control current signal and provide a filtered output. The voltage-controlled oscillator is operable to receive the filtered output and provide a controlled output. The frequency divider is configured to receive at least a portion of the controlled output and generate the feedback clock signal.

The problem of charge pump noise in PLL designs while maintaining reasonable area consumption and power efficiency is further solved by a method, comprising: receiving a reference current by a tail transistor, the tail transistor operable to generate an N-side tail current based on the reference current; receiving, by a DN transistor, a DN signal from a phase-frequency detector, the DN transistor operable to connect a DN source receiving a down current to a DN drain, electrically coupled to the tail transistor, in response to the DN signal; tying a top plate of a sampling capacitor to a voltage buffer, and electrically coupling the bottom plate of the sampling capacitor to a discharge source of a discharge transistor to supply a discharge current to the discharge source; providing a DIS signal to the discharge transistor to draw charges on the bottom plate of the sampling capacitor through the discharge transistor; and tying the bottom plate of the sampling capacitor to the voltage buffer and connecting the top plate of the sampling capacitor to the output node to generate an offset current at the output node and to provide a down current to the tail transistor, the offset current being a control signal current.

The foregoing summary provides an overview of certain selected implementations or embodiments disclosed herein, and is not intended to describe every aspect, embodiment, implementation, feature, or advantage of the disclosure exhaustively or comprehensively. Therefore, this summary should not be construed in such a way to limit the scope of this disclosure or to limit the scope of the claims. The details of one or more implementation or embodiment disclosed herein are set forth in the accompanying drawings and descriptions below. Other aspects, features, implementations, embodiments, and advantages will become readily apparent in view of the description, the drawings, and the claims set forth herein.

Implementations of the above techniques include methods, apparatus, systems, and computer program products are described. One such computer program product is suitably embodied in a non-transitory computer-readable medium that stores instructions executable by one or more processors. The instructions are configured to cause the one or more processors to perform the above-described actions.

The details of one or more implementations of the subject matter of this specification are set forth in the accompanying drawings and the description below. Other aspects, features and advantages will become apparent from the description, the drawings, and the claims.

### BRIEF DESCRIPTION OF THE DRAWINGS

The accompanying drawings, which are incorporated in and constitute a part of this specification, illustrate one or more implementations described herein and, together with the description, explain these implementations. The drawings are not intended to be drawn to scale, and certain features and certain views of the figures may be shown exaggerated, to scale or in schematic in the interest of clarity and conciseness. Not every component may be labeled in every drawing. Like reference numerals in the figures may represent and refer to the same or similar element or function. In the drawings:

FIG. 1 is a block diagram of an exemplary embodiment of a phase-locked loop circuit constructed in accordance with the present disclosure.

FIG. 2 is a schematic of an exemplary embodiment of a charge pump circuit constructed in accordance with the present disclosure.

FIG. 3A is a schematic of an exemplary embodiment of the charge pump circuit of FIG. 2 in a first configuration.

FIG. 3B is a schematic of an exemplary embodiment of the charge pump circuit of FIG. 2 in a second configuration.

FIG. 4 is a timing diagram of an exemplary embodiment of signals of components of the charge pump during operation as constructed in accordance with the present disclosure.

FIG. 5 is a flow chart of an exemplary embodiment of a charge pump process 500 constructed in accordance with the present disclosure.

### DETAILED DESCRIPTION

Before explaining at least one embodiment of the disclosure in detail, it is to be understood that the disclosure is not limited in its application to the details of construction, experiments, exemplary data, and/or the arrangement of the components set forth in the following description or illustrated in the drawings unless otherwise noted.

The disclosure is capable of other embodiments or of being practiced or carried out in various ways. Also, it is to be understood that the phraseology and terminology employed herein is for purposes of description and should not be regarded as limiting.

As used in the description herein, the terms “comprises,” “comprising,” “includes,” “including,” “has,” “having,” or any other variations thereof, are intended to cover a non-exclusive inclusion. For example, unless otherwise noted, a process, method, article, or apparatus that comprises a list of elements is not necessarily limited to only those elements but may also include other elements not expressly listed or inherent to such process, method, article, or apparatus.

Further, unless expressly stated to the contrary, “or” refers to an inclusive and not to an exclusive “or”. For example, a condition A or B is satisfied by one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the inventive concept. This description should be read to include one or more, and the singular also includes the plural unless it is obvious that it is meant otherwise. Further, use of the term “plurality” is meant to convey “more than one” unless expressly stated to the contrary.

As used herein, qualifiers like “substantially,” “about,” “approximately,” and combinations and variations thereof, are intended to include not only the exact amount or value that they qualify, but also some slight deviations therefrom, which may be due to computing tolerances, computing error, manufacturing tolerances, measurement error, wear and tear, stresses exerted on various parts, and combinations thereof, for example.

As used herein, any reference to “one embodiment,” “an embodiment,” “some embodiments,” “one example,” “for example,” or “an example” means that a particular element, feature, structure, or characteristic described in connection with the embodiment is included in at least one embodiment and may be used in conjunction with other embodiments. The appearance of the phrase “in some embodiments” or “one example” in various places in the specification is not necessarily all referring to the same embodiment, for example.

The use of ordinal number terminology (i.e., “first”, “second”, “third”, “fourth”, etc.) is solely for the purpose of differentiating between two or more items and, unless explicitly stated otherwise, is not meant to imply any sequence or order of importance to one item over another.

The use of the term “at least one” or “one or more” will be understood to include one as well as any quantity more than one. In addition, the use of the phrase “at least one of X, Y, and Z” will be understood to include X alone, Y alone, and Z alone, as well as any combination of X, Y, and Z.

The term “PCB” as used herein means a printed circuit board. In some embodiments, a PCB may include one or more integrated circuit. The term “trace” as used herein means a conductive path on at least one layer of the printed circuit board that extends from a first location to a second location. The trace is composed of one or more conductive material.

As used herein, the term “IC” means an integrated circuit. An integrated circuit may be any electronic circuit formed on a semiconductor material, such as silicon, in which a plurality of active and passive circuit elements, including, for example, transistors, diodes, resistors, and capacitors, are fabricated and interconnected. The IC may include multiple layers of metallization and dielectric materials formed in a stack on the semiconductor substrate material. In some embodiments, the IC may be a monolithic integrated circuit where all circuit elements and their interconnections are formed within or on a single semiconductor substrate. In other embodiments, the integrated circuit may be a hybrid integrated circuit where circuit elements are formed on multiple semiconductor substrates that are interconnected using wire bonding, flip-chip bonding, or other semiconductor packaging techniques to form a complete circuit within the package housing. The IC may be packaged to facilitate electrical connection to other circuit elements via pins, balls, leads, or other connection structures extending from a package housing the IC. As used herein, circuitry may refer to an integrated circuit, or a component of an integrated circuit.

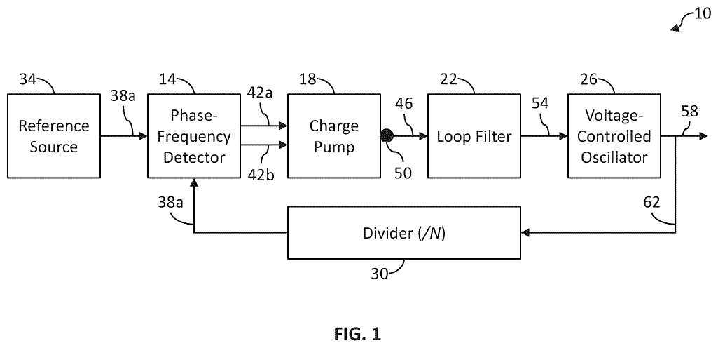

Referring now to the drawings, and in particular to FIG. 1, shown therein is a block diagram of an exemplary embodiment of a phase-locked loop circuit 10 constructed in accordance with the present disclosure. The phase-locked loop circuit 10 (hereinafter PLL 10) generally comprises a phase-frequency detector 14 (hereinafter PFD 14), a charge pump 18, a loop filter 22, a voltage-controlled oscillator 26 (hereinafter VCO 26) and a divider circuit 30. In one embodiment, the PLL 10 is an analog phase-locked loop circuit. In one embodiment, the PLL 10 may be provided in a single integrated circuit, IC, or may be comprised of more than one IC communicably coupled together. For example, one or more of the PFD 14, charge pump 18, loop filter 22, VCO 26 and divider circuit 30 may be provided on a single IC or may be provided on a plurality of ICs. Further, each of the PFD 14, charge pump 18, loop filter 22, VCO 26 and divider circuit 30 may be provided on a single IC or may be provided on a plurality of ICs coupled together.

The PFD 14 may receive at least two clock signals 38. The clock signals 38 may include, for example, a reference clock signal 38a, e.g., from a reference source 34, and a feedback clock signal 38b from the divider circuit 30.

The PFD 14 compares the reference clock signal 38a with the feedback clock signal 38b and generates control signals 42 based on phase and/or frequency differences between the clock signals 38. The control signals 42 include an up signal 42a and a down signal 42b provided to the charge pump 18.

The charge pump 18 receives the control signals 42 and generates a control current signal 46, based on the up signal 42a and down signal 42b, at an output node 50. The output node 50 may be, for example, a lead, trace, or other signal-conductor extending from the charge pump 18 and carrying the control current signal 46. The control current signal 46 is provided to the loop filter 22, which converts the control current signal 46 to a control voltage signal 54 having a determined voltage.

The VCO 26 receives the control voltage signal 54 and generates an output clock signal 58 having an output frequency. The output clock signal 58 has a frequency controlled by the determined voltage of the control voltage signal 54. The divider circuit 30 receives at least a portion 62 of the output clock signal 58 and divides the output frequency by a predetermined factor, N, to generate the feedback clock signal 38b.

The number of devices illustrated in FIG. 1 are provided for explanatory purposes. In practice, there may be additional devices, fewer devices, different devices, or differently arranged devices than are shown in FIG. 1. Furthermore, two or more of the devices illustrated in FIG. 1 may be implemented within a single device, e.g., may be provided on a single IC, or a single device illustrated in FIG. 1 may be implemented as multiple, distributed devices, e.g., implemented on more than one IC. Additionally, one or more of the devices illustrated in FIG. 1 may perform one or more functions described as being performed by another one or more of the devices illustrated in FIG. 1.

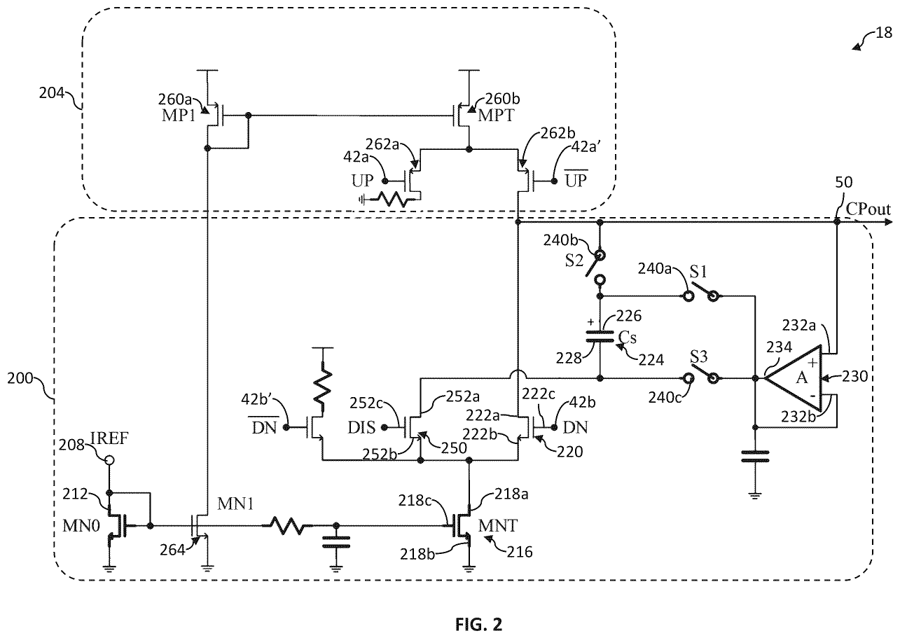

Referring now to FIG. 2, shown therein is a circuit diagram of an exemplary embodiment of the charge pump 18, constructed in accordance with the present disclosure. As shown the charge pump 18 generally comprises circuitry, including an NMOS-side circuitry 200 operable to receive the down signal 42b (and a down-bar signal 42b′) and a PMOS-side circuitry 204 operable to receive the up signal 42a (and an up-bar signal 42a′).

Generally, the charge pump 18 receives a reference current 208, entering the charge pump 18 via reference current input 212. As shown in FIG. 2, the reference current input 212 may be configured to receive the reference current 208 and, in some embodiments, may be a diode-connected transistor, i.e., an NMOS transistor having a source electrically coupled to a gate.

The charge pump 18 further includes a tail transistor 216, e.g., an NMOS transistor, comprising at least a first source 218a, a first drain 218b, and a first gate 218c. The first gate 218c may be configured to receive the reference current 208. The first source 218a may be configured to generate a down current source when the first gate 218c receives the reference current 208. In this way, the tail transistor 216 by generating the down signal current (e.g., a “pull down” signal current), the tail transistor 216 may be considered an N-side tail current source. In one embodiment, the reference current input 212 and the tail transistor 216 may match, e.g., have the same or similar electrical properties. The reference current input 212 and the tail transistor 216 may comprise, for example, MOSFETs.

The charge pump 18 further includes a DN transistor 220 comprising a DN source 222a, a DN drain 222b, and a DN gate 222c. The DN source 222a may be electrically coupled to the output node 50 and may be operable to receive the down signal current generated by the tail transistor 216. The DN drain 222b may be electrically coupled to the first source 218a of the tail transistor 216. The DN gate 222c may be operable to receive the down signal 42b from the PFD 14 and to connect the DN source 222a to the DN drain 222b in response to the down signal 42b from the PFD 14 being high, for example, the gate-to-source voltage is greater than the threshold voltage of the DN gate 222c. The DN transistor 220 may be, for example, a MOSFET.

The charge pump 18 further comprises a sampling capacitor 224 having a top plate 226 and a bottom plate 228. In one embodiment, the sampling capacitor 224 may be a polarized capacitor.

The charge pump 18 may further comprise a voltage buffer 230 having a first buffer input 232a, a second buffer input 232b, and a buffer output 234. The voltage buffer 230 may be constructed as an op-amp. The first buffer input 232a may be a positive input and may be coupled to the output node 50 to receive control current signal 46 and the second buffer input 232b may be a negative input and may be coupled to the buffer output 234. In this way, the voltage buffer 230 may be a negative feedback op-amp.

The charge pump 18 may further comprise a plurality of switches 240. Each of the plurality of switched 240 may be, for example, a transistor, such as a MOSFET. The plurality of switches 240 may include a first switch 240a, a second switch 240b, and a third switch 240c. Each switch 240 of the plurality of switches 240 may have a switch state being one of: closed and opened. In one embodiment, each of the plurality of switches 240 may be a Metal-Oxide-Semiconductor Field-Effect Transistor (MOSFET).

The first switch 240a may be electrically coupled between the top plate 226 of the sampling capacitor 224 and the buffer output 234. The first switch 240a may have a first switch state being one of: closed and opened. The second switch 240b may be coupled between the output node 50 and the top plate 226 of the sampling capacitor 224. The second switch 240b may have a second switch state being one of: closed and opened. The third switch 240c may be electrically coupled between the bottom plate 228 of the sampling capacitor 224 and the buffer output 234 of the voltage buffer 230. The third switch 240c may have a third switch state. The second switch and the third switch may have respective switch states that are synchronized, e.g., have the same switch state, for example, by being actuated by a same signal. In this way, the third switch 240c may be said to have the second switch state.

The charge pump 18 may further comprise a discharge transistor 250, i.e., an NMOS transistor, having a discharge source 252a, a discharge drain 252b, and a discharge gate 252c. The discharge source 252a may be electrically disposed between the third switch 240c and the bottom plate 228 of the sampling capacitor 224. The discharge drain 252b may be electrically coupled to the first source 218a of the tail transistor 216. The discharge gate 252c may be configured to receive a discharge signal IpcG. The discharge signal IpcG may be supplied at a duty cycle based on a desired offset current. The discharge transistor 250 may be, for example, a MOSFET.

In operation, the offset current, I_{OS}, may be generated by the unconventional arrangement of the sampling capacitor 224, the voltage buffer 230, the switches 240, and the discharge transistor 250. In one embodiment, the charge pump 18 may be said to operate in two phases: a frequency acquisition phase and a locked phase. The PMOS-side circuitry 204, comprising a first PMOS transistor 260a, a second PMOS transistor 260b, a first UP transistor 262a, and a second UP transistor 262b, are controlled by the up signals 42a and may only be active during the frequency acquisition phase. Once the PLL 10 is locked, e.g., the in locked phase, the up-bar signal 42a′ will never go low, e.g., the gate-to-source voltage is not lower than the threshold voltage of the gate of the second UP transistor 262b, due to the offset current, thereby keeping the PMOS-side circuitry 204 “dormant,” i.e., noise contributed by the four PMOS transistors 260a-b, 262a-b, does not affect the control current signal 46.

Given that the direction of the reference current 208 is downward flowing into the reference current input 212, the effective offset current is downward, thereby removing the charges from the loop filter 22 while the up signal 42a is generated by the second PMOS transistor 260b, i.e., PMOS current source. All effective current sources in the NMOS-side circuitry 200 are retained to avoid extra noise accumulation due to PMOS-side current mirroring.

The number of devices illustrated in FIG. 2 are provided for explanatory purposes. In practice, there may be additional devices, fewer devices, different devices, or differently arranged devices than are shown in FIG. 2. Furthermore, two or more of the devices illustrated in FIG. 2 may be implemented within a single device, e.g., may be provided on a single IC, or a single device illustrated in FIG. 2 may be implemented as multiple, distributed devices, e.g., implemented on more than one IC. Additionally, one or more of the devices illustrated in FIG. 2 may perform one or more functions described as being performed by another one or more of the devices illustrated in FIG. 2.

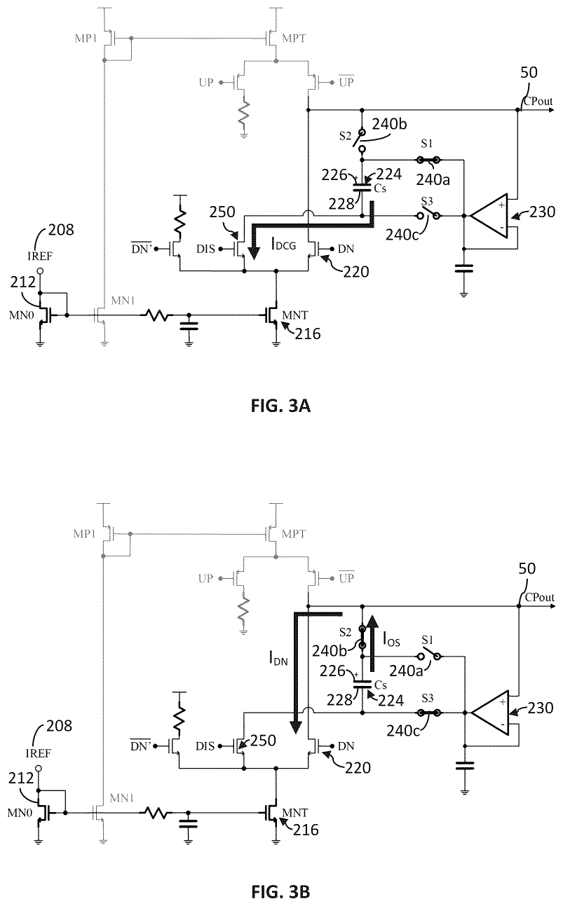

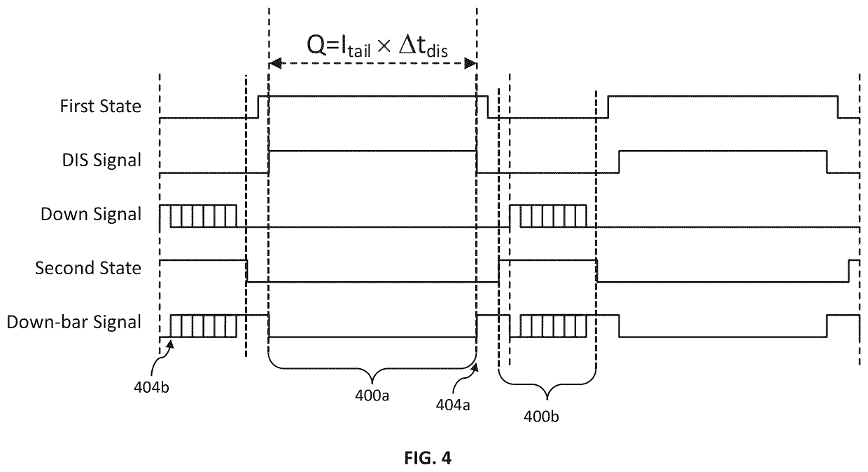

Referring now to FIGS. 3A-3B, in combination, shown therein is a circuit diagram of the charge pump 18 in a first configuration at a first period of time in FIG. 3A and in a second configuration at a second period of time in FIG. 3B. Shown in FIG. 4 is a timing diagram of an exemplary embodiment of the state of components of the charge pump 18 during operation as constructed in accordance with the present disclosure.

At the first period of time 400a, as shown in FIGS. 3A and 4, the charge pump 18 is in the first configuration wherein the first switch 240a has the first state as closed and the second switch state is opened, thereby electrically coupling the top plate 226 of the sampling capacitor 224 to the buffer output 234 and electrically coupling the bottom plate 228 of the sampling capacitor 224 to the discharge source 252a of the discharge transistor 250 to supply the discharge current, I_{DCG}, to the discharge source 252a.

As shown in FIG. 3A, the discharge current, IpcG, draws charges from the bottom plate 228 of the sampling capacitor 224 through the discharge transistor 250 controlled by the discharge signal, DIS. While the discharge signal, DIS, is high, e.g., during the first period of time 400a, a positive charge accumulates on the top plate 226 of the sampling capacitor 224. After the discharge signal, DIS, goes back to low at a first time 404a, the positive charge will have an accumulated value of Iₜₐᵢₗ×Δt_{dis}, e.g., the offset current, on the top plate 226 of the sampling capacitor 224, where Δt_{dis} is a duration that the discharge signal, DIS, is enabled, i.e., the duty cycle of the discharge signal DIS.

Δt the second period of time 400b, as shown in FIGS. 3B and 4, the charge pump 18 is in the second configuration wherein the first switch state is set to opened and the second switch state is set to closed to electrically couple the bottom plate 228 of the sampling capacitor 224 to the buffer output 234 and to electrically couple the top plate 226 of the sampling capacitor 224 to the output node 50 to provide both the offset current, I_{OS}, to the output node 50 and the down signal current, I_{DN}, to the tail transistor 216. The down signal current, I_{DN}, of the charge pump 18 is thus generated by diverting the N-side tail current (Iₜₐᵢₗ) flowing through the tail transistor 216, when the “DN” signal 42b issued by the PFD 14 goes high. The offset current, I_{OS}, is thus generated from the top plate 226 of the sampling capacitor 224.

Δt the moment when the first switch 240a has the first state of open while both the second switch 240b and the third switch 240c have the second state of closed, i.e., during the second period of time 400b, the bottom plate 228 of the sampling capacitor 224 is tied to the buffer output 234 of the voltage buffer 230, while the top plate 226 of the sampling capacitor 224 is connected to the output node 50 to provide the offset current, I_{OS}, as the control current signal 46, and the down current, I_{DN}. This flip around action is equivalent to having a pull up offset current dumping the positive charge on the top plate 226 onto the loop filter 22, e.g., via the output node 50.

In this way, both the offset current, I_{OS}, and the down current, I_{DN}, are generated by the same current source, i.e., the sampling capacitor 224, resulting in both the offset current, I_{OS}, and the down current, I_{DN}, being highly correlated. A low-frequency part of an aggregated current noise, Iₜₙ, from the tail current source, Iₜₐᵢₗ, may be cancelled, or minimized, during this “chopping” operation, while a high-frequency part of the aggregated current noise, Iₜₙ, may be naturally filtered out by the loop filter 22. That is, there is effectively a chopping operation which cancels, or minimizes, the low-frequency (e.g., 1/f) noise in the charge pump 18. Thus, there is no need to make the size of the tail current source excessively large to minimize the in-band phase noise of the PLL 10 as has traditionally been required.

As shown in FIG. 4, most of the period of the time when the tail current, Iₜₐᵢₗ, is not used, e.g., outside the first period of time 400a, the down current, I_{DN}, is generated to discharge the sampling capacitor 224, as shown in FIG. 3A. In one embodiment, during the locked phase, the “DN” signal 42b stays high based on a relative phase of the reference clock signal 38a with the feedback clock signal 38b as determined by the PFD 14, and may stay high for a relatively small portion of a reference clock cycle of the reference clock signal 38a.

The period of the down signal 42b high could be variable if the PLL 10 is in fractional-N operation. To ensure safe operation in this embodiment, there may be guard bands among different discharging phases and charging phases. Thus, there may still be a period of time when the tail current, Iₜₐᵢₗ, is being “wasted,” i.e., when the down-bar signal 42b′ goes high, e.g., at a second time 404b.

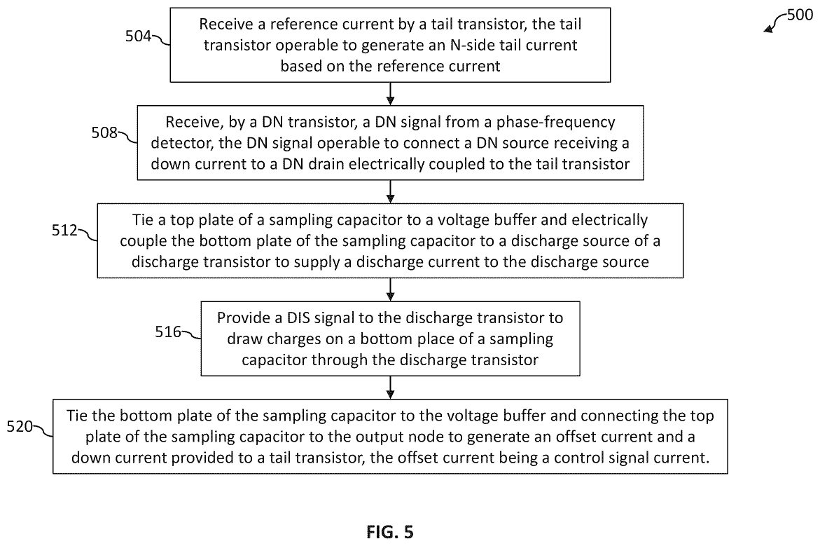

Referring now to FIG. 5, shown therein is a flow chart of an exemplary embodiment of a charge pump process 500 constructed in accordance with the present disclosure. The charge pump process 500 generally comprises: receiving a reference current by a tail transistor (step 504); receiving, by a DN transistor, a DN signal from a phase-frequency detector (step 508); tying a top plate of a sampling capacitor to a voltage buffer and electrically coupling the bottom plate of the sampling capacitor to a discharge source of a discharge transistor (step 512); providing a DIS signal to the discharge transistor (step 516); and tying the bottom plate of the sampling capacitor to the voltage buffer and connecting the top plate of the sampling capacitor to the output node (step 520).

In one embodiment, receiving the reference current by the tail transistor (step 504) includes receiving the reference current 208 by the tail transistor 216 wherein the tail transistor 216 is operable to receive a down current and to generate an N-side tail current based on the reference current 208.

In one embodiment, receiving the reference current by the tail transistor (step 504) further includes receiving the reference current 208 by the reference current input 212. The reference current input 212 may be a diode-connected transistor matched to the tail transistor 216.

In one embodiment, receiving, by the DN transistor, the DN signal from the phase-frequency detector (step 508) includes receiving, by the DN transistor 220 the down signal 42b from the phase-frequency detector 14. The DN transistor 220 may be operable to connect the DN source 222a, receiving the down current, to the DN drain 222b, electrically coupled to the tail transistor 216, in response to the down signal 42b.

In one embodiment, tying the top plate of the sampling capacitor to the voltage buffer and electrically coupling the bottom plate of the sampling capacitor to the discharge source of the discharge transistor (step 512) includes tying the top plate 226 of the sampling capacitor 224 to the voltage buffer 230 and electrically coupling the bottom plate 228 of the sampling capacitor 224 to the discharge source 252a of the discharge transistor 250 to supply a discharge current to the discharge source 252a.

In one embodiment, tying the top plate of the sampling capacitor to the voltage buffer and electrically coupling the bottom plate of the sampling capacitor to the discharge source of the discharge transistor (step 512) includes closing the first switch 240a and opening the second switch 240b and the third switch 240c. In one embodiment, closing the first switch 240a includes providing a first control signal to the first switch 240a and opening the first switch 240a includes removing the first control signal from the first switch 240a. Further, in one embodiment, closing the second switch 240b and the third switch 240c includes providing a second control signal to the second switch 240b and to the third switch 240c and opening the second switch 240b and the third switch 240c includes removing the second control signal from the second switch 240b and the third switch 240c.

In one embodiment, when the first switch is a first MOSFET, the second switch is a second MOSFET, and the third switch is a third MOSFET, tying the top plate of the sampling capacitor to the voltage buffer and electrically coupling the bottom plate of the sampling capacitor to the discharge source of the discharge transistor (step 512) includes providing a first signal to the first MOSFET and providing a second signal to the second MOSFET and to the third MOSFET.

In one embodiment, providing the DIS signal to the discharge transistor (step 516) includes providing the DIS signal to the discharge gate 252c of the discharge transistor 250 to draw charges on the bottom plate 228 of the sampling capacitor 224 through the discharge transistor 250 and the tail transistor 216.

In one embodiment, tying the bottom plate of the sampling capacitor to the voltage buffer and connecting the top plate of the sampling capacitor to the output node (step 520) includes tying the bottom plate 228 of the sampling capacitor 224 to the voltage buffer 230 and connecting the top plate 226 of the sampling capacitor 224 to the output node 50 to generate an offset current at the output node 50 and provide a down current to the tail transistor 216. The offset current may be the control current signal 46.

In one embodiment, tying the bottom plate of the sampling capacitor to the voltage buffer and connecting the top plate of the sampling capacitor to the output node (step 520) includes opening the first switch 240a and closing the second switch 240b and the third switch 240c.

From the above description, it is clear that the inventive concepts disclosed and claimed herein are well adapted to carry out the objects and to attain the advantages mentioned herein, as well as those inherent in the invention. While exemplary embodiments of the inventive concepts have been described for purposes of this disclosure, it will be understood that numerous changes may be made which will readily suggest themselves to those skilled in the art and which are accomplished within the spirit of the inventive concepts disclosed and claimed herein.

What is claimed is:

1. A charge pump circuit, comprising:
an output node having a control current signal;
a reference current input configured to receive a reference current;
a tail transistor having a first source, a first drain, and a first gate, the first gate configured to receive the reference current, the first source configured to receive a down current, and the first drain configured to output an N-side tail current;
a DN transistor having a DN source coupled to the output node and operable to receive the down current, a DN drain coupled to the first source of the tail transistor, and a DN gate operable to receive a DN signal from a phase-frequency detector and connect the DN source to the DN drain in response to the DN signal from the phase-frequency detector being high;
a sampling capacitor having a top plate and a bottom plate;
a voltage buffer having a first buffer input, a second buffer input, and a buffer output, the first buffer input coupled to the output node to receive the control current signal and the second buffer input coupled to the buffer output;
a plurality of switches, comprising:
a first switch coupled between the top plate of the sampling capacitor and the buffer output, the first switch having a first switch state being one of: closed and opened;
a second switch coupled between the output node and the top plate of the sampling capacitor, the second switch having a second switch state being one of: closed and opened; and
a third switch coupled between the bottom plate of the sampling capacitor and the buffer output, the third switch having the second switch state; and
a discharge transistor having a discharge source disposed between the third switch and the bottom plate of the sampling capacitor, a discharge drain coupled to the first source of the tail transistor; and a discharge gate operable to receive a discharge signal;
wherein in a first configuration, the first switch state is closed to electrically couple the top plate of the sampling capacitor to the buffer output and the second switch state is opened to electrically couple the bottom plate of the sampling capacitor to the discharge source of the discharge transistor to supply a discharge current to the discharge source; and
wherein in a second configuration, the first switch state is opened and the second switch state is closed to electrically couple the bottom plate of the sampling capacitor to the buffer output and to electrically couple the top plate of the sampling capacitor to the output node to provide both an offset current to the output node and the down current to the tail transistor.

2. The charge pump circuit of claim 1, wherein the reference current input is a diode-connected transistor.

3. The charge pump circuit of claim 1, wherein the discharge signal is provided with a duty cycle; and wherein the duty cycle determines the offset current as a percentage of the control current signal.

4. The charge pump circuit of claim 1, wherein the sampling capacitor is a polarized capacitor.

5. The charge pump circuit of claim 1, wherein the voltage buffer is a negative-feedback op-amp.

6. The charge pump circuit of claim 1, wherein the plurality of switches are constructed as a plurality of transistors.

7. The charge pump circuit of claim 6, wherein the plurality of transistors are a plurality of MOSFETs.

8. A phase-locked loop system, comprising:
a phase-frequency detector operable to receive a reference clock signal and a feedback clock signal and to transmit a DN signal and a UP signal;
a charge pump having a first configuration and a second configuration, the charge pump, comprising:
a PMOS-side circuitry operable to receive the UP signal;
an output node having a control current signal;
a reference current input configured to receive a reference current;
a tail transistor having a first source, a first drain, and a first gate, the first gate configured to receive the reference current, the first source configured to receive a down current, and the first drain configured to output an N-side tail current;
a DN transistor having a DN source coupled to the output node and operable to receive the down current, a DN drain coupled to the first source of the tail transistor, and a DN gate operable to receive a DN signal from the phase-frequency detector and connect the DN source to the DN drain in response to the DN signal from the phase-frequency detector being high;
a sampling capacitor having a top plate and a bottom plate;
a voltage buffer having a first buffer input, a second buffer input, and a buffer output, the first buffer input coupled to the output node to receive the control current signal and the second buffer input coupled to the buffer output;
a plurality of switches comprising:
a first switch coupled between the top plate of the sampling capacitor and the buffer output, the first switch having a first switch state being one of: closed and opened;
a second switch coupled between the output node and the top plate of the sampling capacitor, the second switch having a second switch state being one of: closed and opened; and
a third switch coupled between the bottom plate of the sampling capacitor and the buffer output, the third switch having the second switch state; and
a discharge transistor having a discharge source disposed between the third switch and the bottom plate of the sampling capacitor, a discharge drain coupled to the first source of the tail transistor; and a discharge gate operable to receive a discharge signal;
wherein in the first configuration, the first switch state is closed to electrically couple the top plate of the sampling capacitor to the buffer output and the second switch state is opened to electrically couple the bottom plate of the sampling capacitor to the discharge source to supply a discharge current to the discharge source; and
wherein in the second configuration, the first switch state is opened and the second switch state is closed to electrically couple the bottom plate of the sampling capacitor to the buffer output and to electrically couple the top plate of the sampling capacitor to the output node to provide both an offset current to the output node and the down current to the tail transistor;
a loop filter in communication with the output node and operable to receive the control current signal and provide a filtered output;
a voltage-controlled oscillator operable to receive the filtered output and provide a controlled output; and
a frequency divider configured to receive at least a portion of the controlled output and generate the feedback clock signal.

9. The phase-locked loop system of claim 8, wherein the reference current input of the charge pump is a diode-connected transistor.

10. The phase-locked loop system of claim 8, wherein the discharge signal is provided with a duty cycle; and wherein the duty cycle determines the offset current as a percentage of the control current signal.

11. The phase-locked loop system of claim 8, wherein the sampling capacitor of the charge pump is a polarized capacitor.

12. The phase-locked loop system of claim 8, wherein the voltage buffer of the charge pump is a negative-feedback op-amp.

13. The phase-locked loop system of claim 8, wherein the plurality of switches is constructed as a plurality of transistors.

14. The phase-locked loop system of claim 13, wherein the plurality of transistors is a plurality of MOSFETs.

15. A method, comprising:
receiving a reference current by a tail transistor, the tail transistor operable to generate an N-side tail current based on the reference current;
receiving, by a DN transistor, a DN signal from a phase-frequency detector, the DN transistor operable to connect a DN source receiving a down current to a DN drain, electrically coupled to the tail transistor, in response to the DN signal;
tying a top plate of a sampling capacitor to a voltage buffer, and electrically coupling a bottom plate of the sampling capacitor to a discharge source of a discharge transistor to supply a discharge current to the discharge source;
providing a DIS signal to the discharge transistor to draw charges on the bottom plate of the sampling capacitor through the discharge transistor; and
tying the bottom plate of the sampling capacitor to the voltage buffer and connecting the top plate of the sampling capacitor to an output node to generate an offset current at the output node and to provide a down current to the tail transistor, the offset current being a control signal current.

16. The method of claim 15, wherein tying the top plate of the sampling capacitor to the voltage buffer, includes closing a first switch and opening a second switch and a third switch.

17. The method of claim 16, wherein tying the bottom plate of the sampling capacitor to the voltage buffer includes opening the first switch and closing the second and third switch.

18. The method of claim 17, wherein closing the first switch includes providing a first control signal to the first switch and opening the first switch includes removing the first control signal from the first switch, and wherein closing the second switch and the third switch includes providing a second control signal to the second switch and to the third switch and opening the second switch and the third switch includes removing the second control signal from the second switch and the third switch.

19. The method of claim 16, wherein the first switch is a first MOSFET, the second switch is a second MOSFET, and the third switch is a third MOSFET and wherein closing the first switch and opening the second switch and the third switch includes providing a first signal to the first MOSFET and providing a second signal to the second MOSFET and to the third MOSFET.

20. The method of claim 15, wherein receiving a reference current by the tail transistor includes receiving the reference current by a reference current input, the reference current input being a diode-connected transistor matched to the tail transistor.
